(19) United States
(12) Patent Application Publication
(10) Pub. No.: US 2018/0312432 A1
(43) Pub. Date: Nov. 1, 2018

(54) GLASS SUBSTRATE AND MANUFACTURING METHOD OF GLASS SUBSTRATE

(71) Applicant: ASAHI GLASS COMPANY, LIMITED, Chiyoda-ku (JP)

(72) Inventors: Kohei HORIUCHI, Chiyoda-ku (JP); Motoshi ONO, Chiyoda-ku (JP); Mamoru ISOBE, Chiyoda-ku (JP); Shigetoshi MORI, Chiyoda-ku (JP)

(73) Assignee: ASAHI GLASS COMPANY, LIMITED, Chiyoda-ku (JP)

(21) Appl. No.: 15/961,297

(22) Filed: Apr. 24, 2018

(30) Foreign Application Priority Data
Apr. 28, 2017 (JP) 2017-090676

(51) Int. Cl. C03C 23/00; H05K 3/00; H05K 1/02; H05K 1/11

(52) U.S. Cl. CPC C03C 23/0025; H05K 3/0029; H05K 1/0269; H05K 1/115; H05K 2201/09609; H05K 2203/107; H05K 2201/09063; H05K 2201/09918; H05K 2201/09936; H05K 2203/0221

(57) ABSTRACT

A glass substrate having a plurality of holes includes a first surface and a second surface, which are opposite to each other. Each of the holes is arranged so as to have an aperture on the first surface. The plurality of holes includes a first hole group including a plurality of first holes having a first aperture diameter including a first variation, and a second hole group including a second hole or a plurality of second holes having a second aperture diameter including a second variation. Each of the first holes has an aspect ratio of greater than 1, and a surface roughness on an inner wall (arithmetic average roughness Ra) of less than 0.1 μm. The second aperture diameter is greater than the first aperture diameter by 15% or more, or less than the first aperture diameter by 15% or more.

### CROSS-REFERENCE TO RELATED APPLICATION

The present application is based on and claims benefit of priority under 35 U.S.C. § 119 of Japanese Patent Application No. 2017-090676, filed Apr. 28, 2017. The contents of the application are incorporated herein by reference in their entirety.

### BACKGROUND OF THE INVENTION

### 1. Field of the Invention

The disclosure herein generally relates to a glass substrate and a manufacturing method of a glass substrate, particularly relates to a glass substrate having holes, such as through holes and/or non-through holes and a manufacturing method thereof.

### 2. Description of the Related Art

Conventionally, a glass substrate having fine holes (so-called perforated glass substrate) has been widely used (See, e.g. Japanese Translation of PCT International Application Publication No. JP-T-2012-519090). For example, a glass substrate having a plurality of fine through holes, in which a conductive material is filled, has been used as a glass interposer.

### SUMMARY OF THE INVENTION

As the aforementioned perforated glass substrates become more widely-used, further additional functions will be required for the perforated glass substrates.

For example, when manufacturing a product such as a glass interposer using the perforated glass substrate, various processes such as polishing and filling a metal material into through holes may be required. However, when the perforated glass substrate at the present stage is used as a product such as a glass interposer, for example, a part of holes are often used as marks for position alignment. In this case, the marks for position alignment may not be read because holes for position alignment cannot be distinguished from holes of the product or the holes for position alignment are too small.

Moreover, for example, in a manufacturing process of products, a great number of perforated glass substrates are handled. In this case, respective perforated glass substrates will be required to be managed by display marks, such as lot numbers or serial numbers. However, at present, the perforated glass substrates are not substantially provided with such a management function.

In this way, for the present perforated glass substrates, it will be difficult to accommodate an additional function that will be required in the future.

The present invention, in consideration of the above-described problem, aims at providing a perforated glass substrate that can realize an additional function such as a position alignment function and/or a lot management function and a manufacturing method thereof.

According to an aspect of the present invention, a glass substrate having a plurality of holes includes a first surface; and a second surface. The first surface and the second surface are opposite to each other.

Each of the holes is arranged so as to have an aperture on the first surface.

The plurality of holes includes a first hole group and a second hole group.

The first hole group includes a plurality of first holes having a first aperture diameter ϕ₁ including a first variation, on the first surface.

The second hole group includes a second hole or a plurality of second holes having a second aperture diameter ϕ₂ including a second variation, on the first surface.

Each of the first holes has an aspect ratio of greater than 1, and a surface roughness on an inner wall (arithmetic average roughness Ra) of less than 0.1 μm.

The second aperture diameter ϕ₂ is greater than the first aperture diameter ϕ₁ by 15% or more, or less than the first aperture diameter ϕ₁ by 15% or more.

Furthermore, according to an aspect of the present invention, a manufacturing method of a glass substrate having a plurality of holes, includes

(1) forming a plurality of first holes on a first surface of a glass plate by irradiating the first surface with a first laser light, the glass plate having the first surface and a second surface opposite to each other,

each of the first holes having a first aperture with a first aperture diameter ϕ₁ including a first variation, on the first surface; and

(2) forming a second hole or a plurality of second holes on the first surface of the glass plate by irradiating the first surface with a second laser light,

each of the second holes having a second aperture with a second aperture diameter ϕ₂ including a second variation, on the first surface.

A process of (1) forming the plurality of first holes and a process of (2) forming the second hole or the plurality of second holes are exchangeable.

The second aperture diameter ϕ₂ is greater than the first aperture diameter ϕ₁ by 15% or more, or less than the first aperture diameter ϕ₁ by 15% or more.

According to an aspect of the present invention, there is provided a perforated glass substrate that can realize an additional function such as a position alignment function and/or a lot management function and a manufacturing method thereof.

### BRIEF DESCRIPTION OF THE DRAWINGS

Other objects, features and advantages of the present invention will become more apparent from the following detailed description when read in conjunction with the accompanying drawings, in which:

FIG. 1 is a perspective view schematically depicting an example of a glass substrate according to an embodiment;

FIG. 2 is a top view schematically depicting an example of a first hole group on the glass substrate according to the embodiment;

FIG. 3 is a top view schematically depicting an example of a second hole group on the glass substrate according to the embodiment;

FIG. 4 is a top view schematically depicting an example of a third hole group on the glass substrate according to the embodiment;

FIG. 5 is a flowchart depicting a flow of a manufacturing method of a glass substrate according to the embodiment;

FIG. 6 is a diagram schematically depicting a glass plate used for the manufacturing method of the glass substrate according to the embodiment;

FIG. 7 is a diagram schematically depicting one step in the manufacturing method of the glass substrate according to the embodiment;

FIG. 8 is a diagram schematically depicting another step in the manufacturing method of the glass substrate according to the embodiment;

FIG. 9 is a graph showing an example of a relation between an irradiation time of a laser light and an aperture diameter of a hole according to the embodiment;

FIG. 10 is a graph showing an example of a relation between a position of a focal point of the laser light and the aperture diameter of the hole according to the embodiment; and

FIG. 11 is a diagram schematically depicting yet another step in the manufacturing method of the glass substrate according to the embodiment.

### DETAILED DESCRIPTION OF THE PREFERRED EMBODIMENTS

In the following, with reference to drawings, embodiments of the present invention will be described.

(Glass Substrate According to Embodiment)

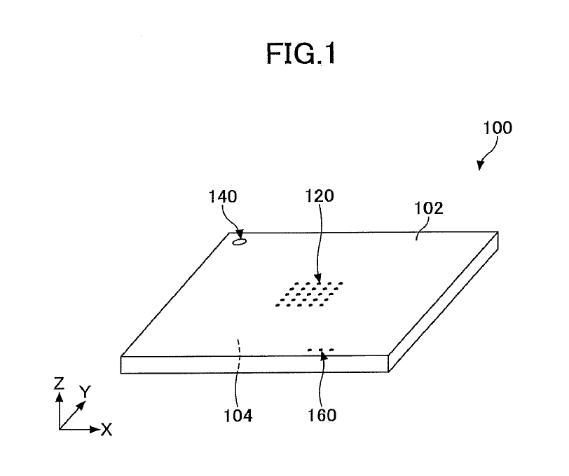

FIG. 1 is a perspective view schematically depicting an example of a glass substrate according to an embodiment (in the following, referred to as a “first glass substrate”).

As illustrated in FIG. 1, the first glass substrate 100 has a first surface 102 and a second surface 104 that are opposite to each other, and has an approximately rectangular shape. However, the shape of the first glass substrate 100 is not particularly limited. The first glass substrate 100 may have various shapes, such as a circle or an ellipse.

The first glass substrate 100 has three types of hole groups, i.e. a first hole group 120, a second hole group 140, and a third hole group 160, on the first surface 102.

FIG. 1 illustrates an example in which the first hole group 120 is arranged approximately at a center of the first surface 102. In contrast, the second hole group 140 is arranged near a corner portion of the first surface 102. Moreover, the third hole group 160 is arranged near one side of the first surface 102.

However, the aforementioned arrangement is merely an example. The arrangement of the first hole group 120, the second hole group 140 and the third hole group 160 is not particularly limited. For example, the first hole group 120 may be arranged in a region other than the center of the first surface 102. Moreover, the second hole group 140 and/or the third hole group 160 may be arranged at the central region of the first surface 102. In the case where the first glass substrate 100 lacks a corner portion, e.g. the glass substrate 100 has a shape of a circle, the second hole group 140 may be arranged near an edge portion of the first surface.

In the following, the first hole group 120, the second hole group 140 and the third hole group 160 will be described in detail with reference to FIGS. 1 to 4.

(First Hole Group 120)

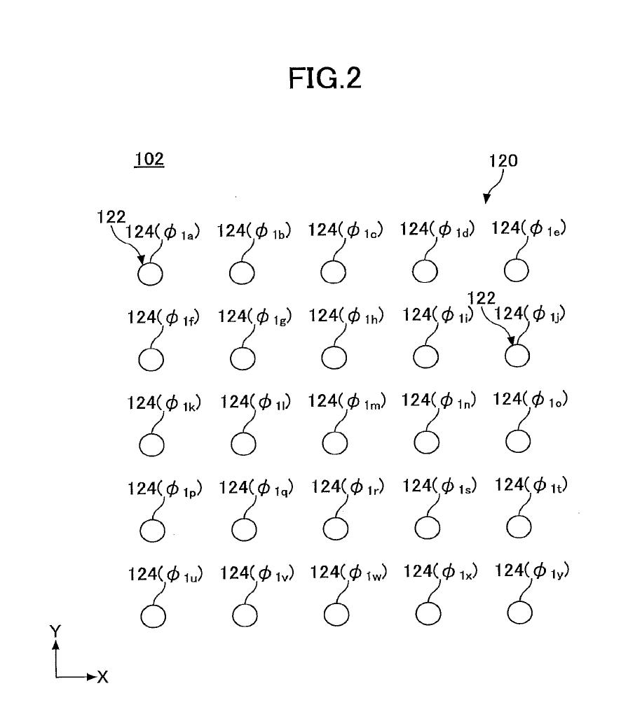

FIG. 2 is a top view schematically depicting the first hole group.

As illustrated in FIG. 2, the first hole group 120 is configured of a plurality of arrays of first holes 122. For example, in FIG. 2, the first holes 122 are arranged forming a matrix with 5 rows and 5 columns in the horizontal direction (X) and the vertical direction (Y) at regular intervals.

However, the aforementioned arrangement is merely an example. The first holes 122 may be arranged in another form. Particularly, a number of the first holes 122 configuring the first hole group 120, in a typical case, falls within a range of 1000 to 1000000. FIG. 2 illustrates the first hole group in a simplified form.

Each of the first holes 122 may be a through hole or may be a non-through hole.

Each of the first holes 122 has an aperture (in the following, referred to as a “first aperture”) 124 on the first surface 102 of the glass substrate 100.

Note that the first holes 122 are ideally formed by an irradiation of laser light so that diameters of the first aperture 124 are the same. However, in practice, in terms of machining accuracy, the diameters of the first apertures 124 may have a variation. Thus, in FIG. 2, the diameter of the first aperture 124 of the first hole 122 is indicated with a parenthesis, such as ϕ₁ₐ, and ϕ_{1b}.

However, the diameter of the first aperture (ϕ₁ₐ, ϕ_{1b}, . . . ) 124 usually follows a normal distribution. Thus, the diameters of the first apertures 124 fall within a prescribed range of variation (in the following, referred to as a “first variation”). In other words, the diameters of the first apertures 124 of the first holes 122 can be substantially regarded as a constant taking into account the “first variation”. In the present application, the diameter of the first aperture 124 regarded as a constant will be defined as a “first aperture diameter ϕ₁”.

In practice, the first aperture diameter ϕ₁ can be obtained by averaging ten diameters of first apertures 124 of first holes 122 randomly sampled from the first hole group 120.

Moreover, the first variation can be defined as a standard deviation σ of the ten diameters of the first apertures 124 that were sampled as above. That is, the first variation can be obtained from the following formula (1) of a standard deviation a.

$$\begin{matrix}[ Math 1 ] & \\ σ = \sqrt{\frac{1}{10 - 1} {\sum }_{i = 1}^{10} {( {φ}_{i} - {φ}_{av} )}^{2}} & ( formula 1 )\end{matrix}$$

where ϕᵢ represents a diameter of the sampled first aperture 124, and ϕₐᵥ is an average of the ten diameters of the sampled first apertures 124, i.e. the first aperture diameter ϕ₁.

Note that the first aperture diameter ϕ₁ can be obtained by specifying six points on an edge of the first aperture by using a reflection type optical microscope (e.g. Asahikogaku MS-200), and calculating from an approximate circle for the six points. Six points may be positions of 0 o'clock, 2 o'clock, 4 o'clock, 6 o'clock, 8 o'clock and 10 o'clock of the edges of the first aperture.

The first aperture diameter ϕ₁ is selected from, for example, a range of 10 μm to 200 μm, preferably, a range of 20 μm to 150 μm, and further preferably, a range of 40 μm to 100 μm. Moreover, the first variation may fall within a range of ±10% of the first aperture diameter ϕ₁.

The first hole group 120 will be used, when a part provided with the first glass substrate 100 is manufactured from the first glass substrate 100 in a following stage, as an essential portion of the part. For example, when a glass interposer is manufactured from the first glass substrate 100, the first hole 122 contained in the first hole group will be used as a through via in which a conductive material will be filled.

Thus, in the following, the first hole group 120 will also be referred to as a “fundamental hole group 120”, and the first hole 122 will also be referred as a “fundamental hole 122”.

Moreover, an aspect ratio of the first hole 122 is greater than 1, and preferably greater than or equal to 2 and less than or equal to 20. A surface roughness of an inner wall (arithmetic average roughness Ra) is less than 0.1 μm, preferably greater than or equal to 0.0001 μm and less than or equal to 0.08 μm, and further preferably greater than or equal to 0.001 μm and less than or equal to 0.06 μm. The aspect ratio means a value obtained by dividing a depth of the first hole 122 (in the case of a through hole, a thickness of the substrate) by the diameter of the first aperture of the first hole 122.

The surface roughness (Ra) of the inner wall of the first hole 122 can be obtained by measuring for a range of 20 mm of the hole in the depth direction using a laser microscope (e.g. Keyence VK9700). A measurement position may be a range excluding the outside of a range from 10% of a depth of the hole from the first surface of the glass substrate to 10% of a depth of the hole from the second surface of the glass substrate, in a cross-section of the hole, i.e. a range from 10% to 90% of the depth of the hole from the first surface of the glass substrate.

The depth of the first hole 122 may be obtained, in the case of a non-through hole, by measuring a distance between the deepest point (hole lowest end) observed in the cross section of the hole using a transmission type optical microscope (e.g. Olympus BX51) and a plane that is the same plane as the glass surface.

By configuring the first hole 122 as above, for example, in a substrate provided with a penetration electrode, such as a glass interposer, a high-density fine via can be formed. Moreover, it becomes easier to fill a conductive material.

(Second Hole Group 140)

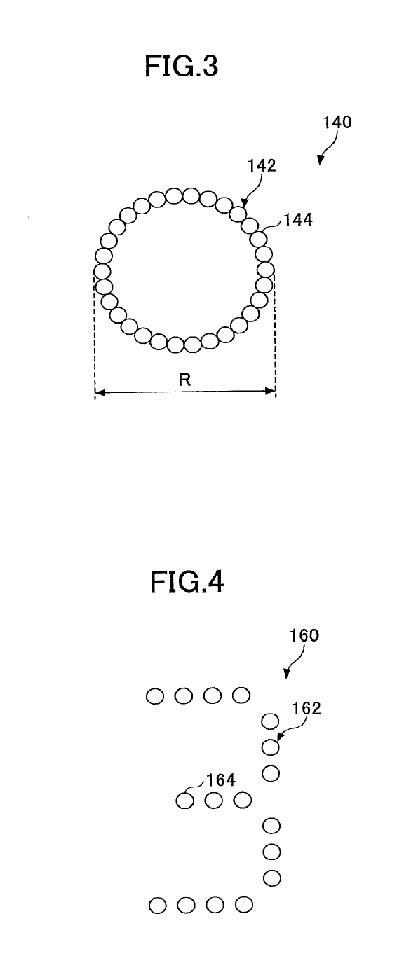

FIG. 3 is a top view schematically depicting a second hole group 140.

As illustrated in FIG. 3, the second hole group 140 is configured of an array of a plurality of second holes 142. Each of the second holes 142 may be a through hole or may be a non-through hole.

The second holes 142 are formed by an irradiation of a laser light.

FIG. 3 illustrates the second hole group 140 in which the second holes 142 are arranged in a ring shape (circular ring). Note that, in FIG. 3, adjacent second holes 142 are arranged so as to contact each other. However, the configuration is merely an example, and the adjacent second holes 142 may be arranged so as to overlap with each other or may be arranged so as not to contact each other.

Moreover, the second holes 142 in the second hole group 140 may be arranged in a shape other than a ring.

The respective second holes 142 have apertures (in the following, referred to as “second aperture”) 144 on the first surface 102 of the glass substrate 100.

Note that, also for the second holes 142, in terms of machining accuracy, diameters of the second apertures 144 may have a variation.

However, the diameter of the second aperture 144 usually follows a normal distribution. Thus, the diameters of the second apertures 144 fall within a prescribed range of variation (in the following, referred to as a “second variation”). In other words, the diameters of the second apertures 144 of the second holes 142 can be substantially regarded as a constant taking into account the “second variation”. In the present application, the diameter of the second aperture 144 regarded as a constant will be defined as a “second aperture diameter ϕ₂”.

In practice, the second aperture diameter ϕ₂ can be obtained by averaging ten diameters of second apertures 144 of second holes 142 randomly sampled from the second hole group 140.

Moreover, the second variation can be defined as a standard deviation σ of the ten diameters of the second apertures 144 that were sampled as above. That is, the second variation can be obtained from the aforementioned formula (1).

Moreover, the second aperture diameter ϕ₂ may be calculated in the same way as the first aperture diameter ϕ₁.

The second aperture diameter ϕ₂ is selected from, for example, except for the first aperture diameter ϕ₁, a range of 1 μm to 3000 μm, preferably, a range of 1 μm to 30 μm and 100 μm to 1000 μm. Moreover, the second variation may fall within a range of ±10% of the second aperture diameter ϕ₂.

Here, the second aperture diameter ϕ₂ of the second hole 142 has a feature that the second aperture diameter ϕ₂ is greater than the first aperture diameters ϕ₁ of the first holes 122 by 15% or more, or less than the first aperture diameter ϕ₁ of the first holes 122 by 15% or more.

For example, in the case where the first aperture diameters ϕ₁ of the first holes is 50 μm, the second aperture diameter ϕ₂ of the second hole 142 is selected so as to be less than 42.5 μm or greater than 57.5 μm.

The second hole group 140 may be configured within a region of 1 mm×1 mm on the first surface 102, for example. In FIG. 3, an outer diameter of the ring R may be 1 mm or less, and may be 500 μm or less.

However, the second hole group 140 is not necessarily arranged at one site. For example, in the diagram illustrated in FIG. 1, the second hole groups 140 may be arranged near the respective corner portions of the first surface 102, i.e. at four sites.

Note that, in the case where the second hole groups 140 are present at a plurality of sites, a “region of the second hole group 140” means a region occupied by the second hole group 140 at each site.

The second holes 142 may be formed so that all the adjacent second holes 142 are through holes and are overlapped with or contact each other. In this case, the inside of the ring configured of the second holes 142 is physically penetrated. As a result, in the case of FIG. 3, a hole with a diameter of R (corresponding to the second hole) is formed. By adjusting an extent of overlapping of the second holes 142, the shape of the circle with the diameter R can be made to be a precise circle that is not affected by outer shapes of the respective second holes 142. In this case, the second aperture diameter is R.

Moreover, a hole with a diameter of R may be formed by one second hole 142.

(Third Hole Group 160)

FIG. 4 is a top view schematically depicting the third hole group 160.

As illustrated in FIG. 4 the third hole group 160 is configured of an array of a plurality of third holes 162. Each of the third holes 162 may be a through hole or may be a non-through hole.

The third holes 162 are formed by an irradiation of a laser light.

FIG. 4 illustrates the third hole group 160 such that the third holes 162 are arranged in a shape of a digit “3”. Note that, in FIG. 4, adjacent third holes 162 are arranged so as not to contact each other. However, the configuration is merely an example, and the adjacent third holes 162 may be arranged so as to overlap with each other or may be arranged so as to contact each other.

Moreover, the third holes 162 in the third hole group 160 may be arranged in a shape other than a digit “3”. Furthermore, the third hole group 160 may be formed to configure a plurality of characters, digits and/or symbols by the third holes 162.

The respective third holes 162 have apertures (in the following, referred to as “third aperture”) 164 on the first surface 102 of the glass substrate 100.

Note that, also for the third holes 162, in terms of machining accuracy, diameters of the third apertures 164 may have a variation.

However, the diameters of the third aperture 164 usually follow a normal distribution. Thus, the diameters of the third apertures 164 fall within a prescribed range of variation (in the following, referred to as a “third variation”). In other words, the diameters of the third apertures 164 of the third holes 162 can be substantially regarded as a constant taking into account the “third variation”. In the present application, the diameter of the third aperture 164 regarded as a constant will be defined as a “third aperture diameter ϕ₃”.

In practice, the third aperture diameter ϕ₃ can be obtained by averaging ten diameters of third apertures 164 of third holes 162 randomly sampled from the third hole group 160.

Moreover, the third variation can be defined as a standard deviation σ of the ten diameters of the third apertures 164 that were sampled as above. That is, the third variation can be obtained from the aforementioned formula (1).

Moreover, the third aperture diameter ϕ₃ may be calculated in the same way as the first aperture diameter ϕ₁.

The third aperture diameter ϕ₃ is selected from, for example, except for the first aperture diameter ϕ₁ and the second aperture ϕ₂, a range of 1 μm to 3000 μm, preferably, a range of 1 μm to 30 μm and 100 μm to 1000 μm. Moreover, the third variation may fall within a range of ±10% of the third aperture diameter ϕ₃.

Here, the third aperture diameter ϕ₃ of the third holes 162 has a feature that the third aperture diameter ϕ₃ is greater than the first aperture diameter ϕ₁ of the first holes 122 by 15% or more, or less than the first aperture diameter ϕ₁ of the first holes 122 by 15% or more. Note that the third aperture diameter ϕ₃ is different from the second aperture diameter ϕ₂.

For example, in the case where the first aperture diameter ϕ₁ of the first holes is 50 μm, the third aperture diameter ϕ₃ of the third holes 162 is selected so as to be different from the second aperture diameter ϕ₂, and further, to be less than 42.5 μm or greater than 57.5 μm.

Note that in the first glass substrate 100, the second hole group 140 or the third hole group 160 may be omitted.

In this way, the first glass substrate 100 includes on the first surface 102 at least two types of hole groups, in which diameters of apertures of holes are substantially different from each other. For example, the first glass substrate 100 may have the first hole group 120 and the second hole group 140. Alternatively, the first glass substrate 100 may have the first hole group 120 and the third hole group 160. Alternatively, the first glass substrate 100 may have the first hole group 120, the second hole group 140 and the third hole group 160. Furthermore, the first surface 102 may have four or more types of hole groups.

The “fundamental hole group 120” of the first glass substrate 100 having the aforementioned feature can be used as an essential part of a member provided with the first glass substrate 100, when the member is manufactured in a following stage. Moreover, the remaining hole groups 140, 160 can be used as a part that causes the first glass substrate 100 to realize an additional function.

For example, the first hole group 120 can be used as a “fundamental hole group 120” in which a conductive material will be filled in the following stage, and the second hole group 140 or the third hole group 160 can be used as alignment marks for a position adjustment for the first glass substrate 100. Moreover, for example, the first hole group 120 can be used as the “fundamental hole group 120”, and the second hole group 140 or the third hole group 160 can be used as a distinguishable managing identifier for the first glass substrate 100 (display mark of a lot number, a serial number or the like). Furthermore, for example, the first hole group 120 can be used as the “fundamental hole group 120”, the second hole group 140 can be used as an alignment mark for a position adjustment for the first glass substrate 100, and the third hole group 160 can be used as a distinguishable managing identifier for the first glass substrate 100.

Note that, in the aforementioned description, the second hole group 140 has been assumed to be configured of the plurality of second holes 142. However, the configuration is merely an example, and the second hole group 140 may be configured of a single second hole 142. In this case, the diameter of the second aperture 144 of the second hole 142 is the second aperture diameter ϕ₂. Moreover, the second variation can be regarded as zero.

The aforementioned configuration can also be applied to the third hole group 160.

(Manufacturing Method of Glass Substrate According to Embodiment)

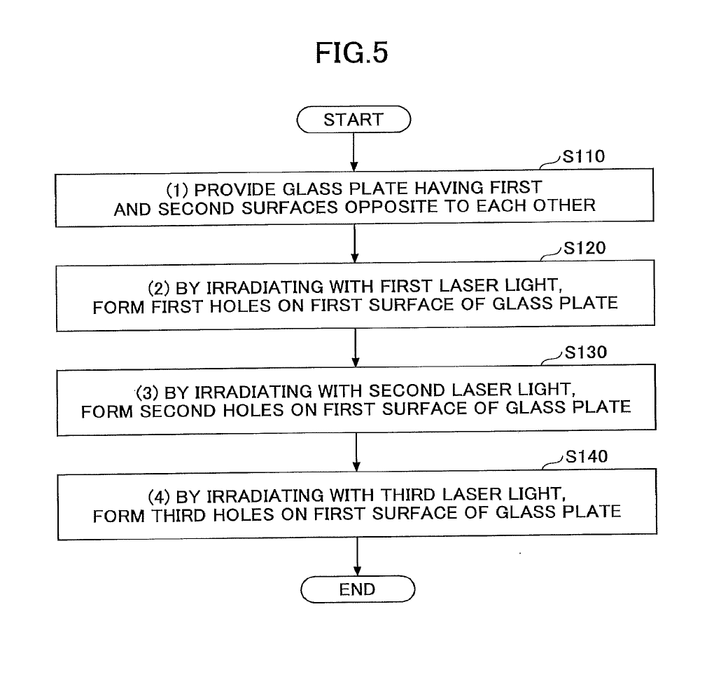

Next, with reference to FIG. 5, an example of a manufacturing method for a glass substrate according to an embodiment will be described.

FIG. 5 is a flowchart schematically depicting a flow of the manufacturing method of a glass substrate according to the embodiment (in the following, referred to as a “first manufacturing method”).

As illustrated in FIG. 5, the first manufacturing method includes

(1) a step of providing a glass substrate having first and second surfaces opposite to each other (step S110);

(2) a step of forming first holes on the first surface of the glass plate by an irradiation of a first laser light (step S120);

(3) a step of forming second holes on the first surface of the glass plate by an irradiation of a second laser light (step S130); and

(4) a step of forming third holes on the first surface of the glass plate by an irradiation of a third laser light (step S140).

However the step (4) is not an indispensable step, and may be omitted. Moreover, the steps (2) to (4) may be performed in any order.

In the following, the respective steps will be described in detail.

(Step S110)

First, a glass plate to be processed is provided.

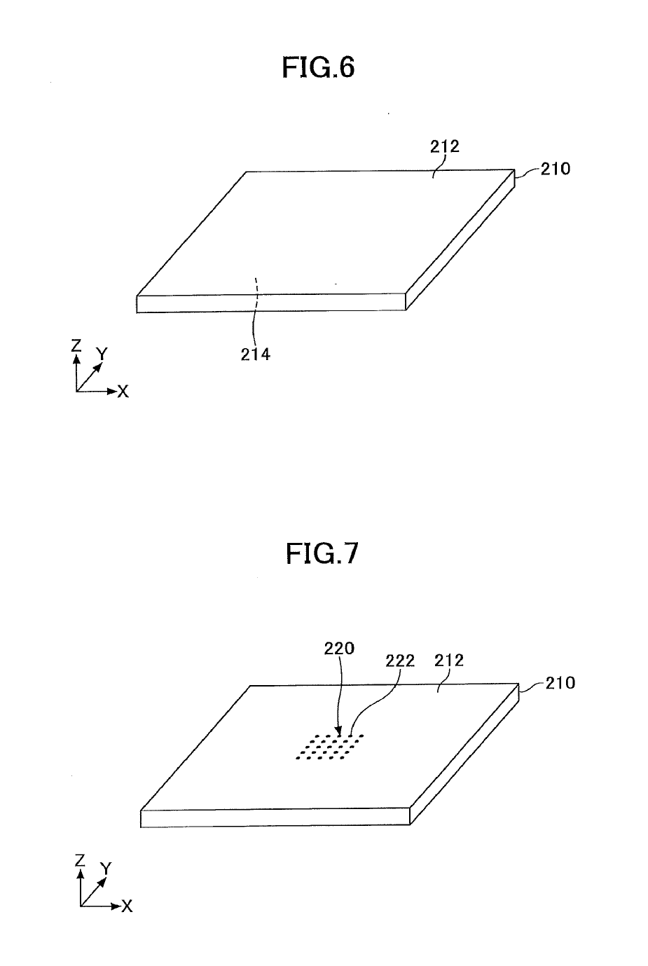

FIG. 6 schematically depicts an example of the glass plate.

As illustrated in FIG. 6, the glass plate 210 has a first surface 212 and a second surface 214.

The glass plate 210 may be configured of a material of any composition. For example, the glass plate 210 may be a quartz glass.

A thickness of the glass plate 210 is not particularly limited. The thickness falls, for example, within a range of 0.03 mm to 1.5 mm, and preferably falls within a range of 0.05 mm to 0.7 mm.

Note that the glass plate 210 does not necessarily have a shape of a rectangle, as shown in FIG. 6, and may have various shapes, such as a circle or an ellipse.

(Step S120)

Next, the first surface 212 of the glass plate 210 is irradiated with a first laser light. Thus, a first hole group is formed on the glass plate 210.

FIG. 7 schematically depicts an example of the glass plate 210 in which a plurality of first holes 222 configuring the first hole group 220 are formed on the first surface 212.

FIG. 7 illustrates the first hole group 222 arranged approximately at the center of the first surface 212 of the glass plate 210. However, the position of the first hole group 220 on the first surface 212 is not particularly limited. Moreover, also a number of the first holes 222 configuring the first hole group 220 is not particularly limited. Note that the first hole group 220 may be arranged at a plurality of sites on the first surface 212.

A type of a first laser light, with which the glass plate 210 is irradiated, is not particularly limited. For example, the first laser light may be a laser light emitted from a CO₂ laser, a YAG laser, a fiber laser, an ultrashort pulsed-laser, or the like.

Note that irradiation conditions for the first laser light for forming the respective first holes 222 are set to be substantially the same in order to form the first holes 222 with the same diameter of apertures (referred to as a “first aperture”, as described above). However, in practice, in terms of machining accuracy, the diameters of the first apertures may have a variation (the first variation, as described above).

However, as described above, the diameters of the first apertures fall within a range of the first variation. In other words, the diameters of the first apertures of the first holes 222 can be substantially regarded as a constant “first aperture diameter ϕ₁” taking into account the first variation.

The first aperture diameter ϕ₁ is selected from, for example, a range of 10 μm to 200 μm. Moreover, the first variation may fall within a range of ±10% of the first aperture diameter ϕ₁.

The first hole 222 is used for a fundamental portion of the manufactured glass substrate as a “fundamental hole”, in the following. Moreover, the first hole 222 has an aspect ratio of greater than 1, and a surface roughness of an inner wall (arithmetic average roughness Ra) of less than 0.1 μm.

(Step S130)

Next, the first surface 212 of the glass plate 210 is irradiated with a second laser light. Thus, a second hole group is formed on the first surface 212 of the glass plate 210.

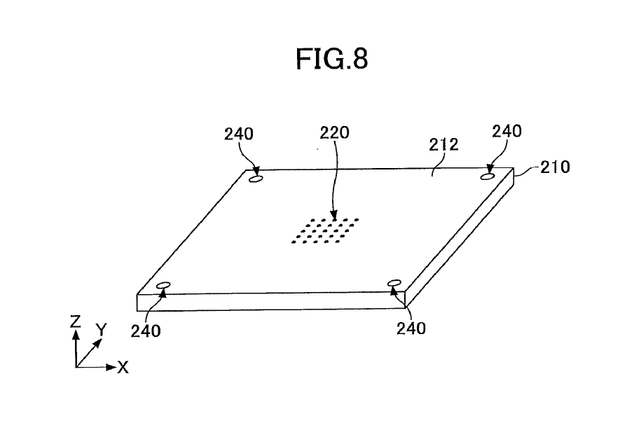

FIG. 8 schematically depicts an example of the glass plate 210, in which the second hole group 240 is formed on the first surface 212.

FIG. 8 illustrates the second hole groups 240 arranged at four sites on the first surface 212. That is, the second hole groups 240 are arranged near the corner portions of the first surface 212 of the glass plate 210, respectively.

However, the position of the second hole group 240 on the first surface 212 is not particularly limited. Moreover, also a number of the second hole groups 240 is not particularly limited.

Note that although it is not clear from FIG. 8, each of the second hole groups 240 is configured of a plurality of second holes. The second holes are arranged, for example, in a shape of a ring, as illustrated in FIG. 3, or other shape, and the second hole group 240 may be configured of the second holes with another arrangement.

The second hole may be a through hole, or may be a non-through hole.

Note that irradiation conditions for the second laser light for forming the respective second holes are set to be substantially the same in order to form the second holes with the same diameter of apertures (referred to as a “second aperture”, as described above). However, in practice, in terms of machining accuracy, the diameters of the second apertures may have a variation (the second variation, as described above).

However, as described above, the diameters of the second apertures fall within a range of the second variation. In other words, the diameters of the second apertures of the second holes can be substantially regarded as a constant “second aperture diameter ϕ₂” taking into account the second variation.

The second aperture diameter ϕ₂ is selected so as to be greater than the first aperture diameter ϕ₁ by 15% or more, or less than the first aperture diameter ϕ₁ by 15% or more.

The second aperture diameter ϕ₂ may be selected from, for example, a range of 1 μm to 3000 μm. Moreover, the second variation may fall within a range of ±10% of the second aperture diameter ϕ₂.

The second hole group 240 can be used as a part that causes the glass substrate to realize an additional function, when the glass substrate is manufactured by the first manufacturing method. For example, the second hole group 240 can be used as alignment marks for a position adjustment for the glass substrate, or as a managing identifier for the glass substrate.

In Step S130, a type of laser device that emits a second laser light, with which the glass plate 210 is irradiated, is not particularly limited. However, the laser used in Step S130 is preferably the same type as the laser used in Step S120. In this case, it becomes unnecessary to change the type of laser between Step S120 and Step S130, and the first manufacturing method can be performed efficiently.

Note that when the aforementioned process is performed, although the same type of laser is used in Step S120 and Step S130, diameters of apertures are required to be different between the first hole 222 and the second hole.

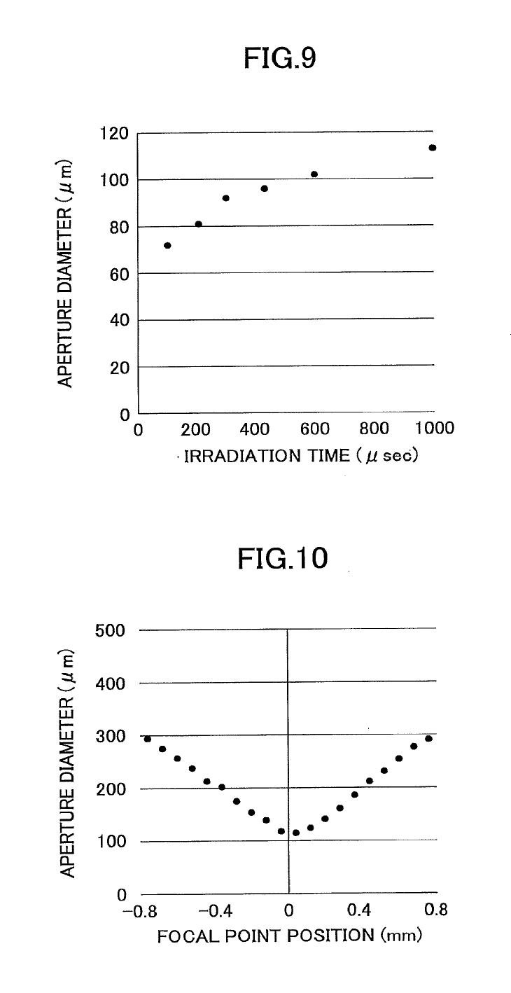

The inventors of the present application have found that the above-described problem can be solved by changing an irradiation time and/or a position of a focal point of a laser light in the irradiation of laser light in Step S120 and Step S130. The method will be described with reference to FIG. 9 and FIG. 10 in the following.

FIG. 9 is a graph showing a relation between an irradiation time of a laser light and an aperture diameter of a hole.

Data obtained by using a glass plate configured of an alkali-free glass and a CO₂ laser are plotted in FIG. 9. The position of a focal point of a laser light was the first surface of the glass plate.

From FIG. 9, it is found that the aperture diameter of a hole varies when the irradiation time of a laser light is changed.

FIG. 10 is a graph showing a relation between the position of a focal point of a laser light and the aperture diameter of the hole. The horizontal axis of the graph indicates a position of a focal point of a laser light in the thickness direction of the glass plate. That is, the position of the focal point of 0 mm means that the position of the focal point of the laser light is on the first surface of the glass plate. A positive value in the horizontal axis indicates a site outside the first surface of the glass plate (opposite to the second surface), and a negative value in the horizontal axis indicates a site inside the first surface of the glass plate (toward the second surface).

Data obtained by using a glass plate configured of an alkali-free glass and a CO₂ laser are plotted in FIG. 10. The irradiation time was 100 μsec.

From FIG. 10, it is found that the aperture diameter of a hole varies with change in the position of focal point of laser light.

As described above, it was found that when the irradiation time of laser light and/or the position of focal point of laser light in Step S130 were different from those in Step S120, the second aperture diameter ϕ₂ of the second holes could be made different from the first aperture diameter ϕ₁ of the first holes 222.

(Step S140)

Next, if necessary, the first surface 212 of the glass plate 210 is irradiated with a third laser light. Thus, a third hole group is formed on the first surface 212 of the glass plate 210. Step S140 may be omitted.

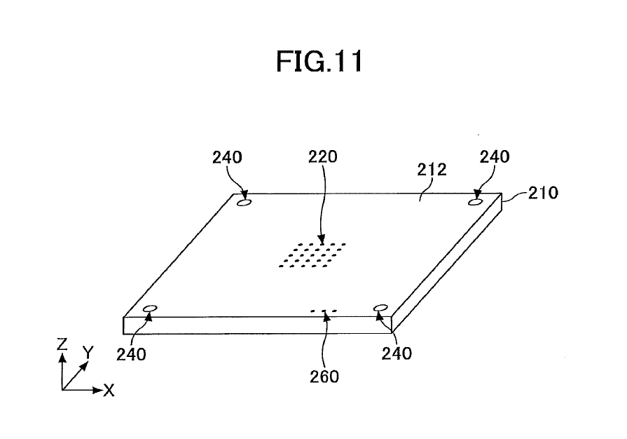

FIG. 11 is a diagram schematically depicting an example of the glass plate 210, in which the third hole group 260 is formed on the first surface 212.

FIG. 11 illustrates an example of the third hole group 260 arranged near one side of the first surface 212. However, the position of the third hole group 260 on the first surface 212 is not particularly limited. Moreover, a number of the third hole group 260 is not necessarily limited to one. The third hole groups 260 may be arranged at a plurality of sites on the first surface 212.

Note that although it is not clear from FIG. 11, the third hole group 260 is configured of a plurality of third holes. The third holes may be arranged, for example, in a shape configuring one or more characters, digits and/or symbols, or other shape. The third hole group 260 may be configured of the arrangement of the third holes, as illustrated in FIG. 4, for example.

The third hole may be a through hole, or may be a non-through hole.

Note that irradiation conditions for the third laser light for forming the respective third holes are set to be substantially the same in order to form the third holes with the same diameter of apertures (referred to as a “third aperture”, as described above). However, in practice, in terms of machining accuracy, the diameters of the third apertures may have a variation (the third variation, as described above).

However, as described above, the diameters of the third apertures fall within a range of the third variation. In other words, the diameters of the third apertures of the third holes can be substantially regarded as a constant “third aperture diameter ϕ₃” taking into account the third variation.

The third aperture diameter ϕ₁ is selected so as to be different from the second aperture diameter ϕ₂. Moreover, the third aperture diameter ϕ₃ is selected so as to be greater than the first aperture diameter ϕ₁ by 15% or more, or less than the first aperture diameter ϕ₁ by 15% or more.

The third aperture diameter ϕ₃ may be selected from, for example, a range of 1 μm to 3000 μm. Moreover, the third variation may fall within a range of ±10% of the third aperture diameter ϕ₃.

The third hole group 260 can be used as a part that causes the glass substrate to realize a further additional function, when the glass substrate is manufactured by the first manufacturing method. For example, the third hole group 260 can be used as a managing identifier for the glass substrate, or as alignment marks for a position adjustment for the glass substrate.

In Step S140, a type of laser device that emits a third laser light, with which the glass plate 210 is irradiated, is not particularly limited. However, the laser used in Step S140 is preferably the same type as at least one of the laser used in Step S120 and the laser used in Step S130. Particularly, the laser for the first laser light, the laser for the second laser light and the laser for the third laser light are preferably the same type. In this case, it becomes unnecessary to change the type of laser among Step S120, Step S130 and Step S140, and the first manufacturing method can be performed efficiently.

As described above, the aforementioned process can be performed by changing the irradiation time of laser light and/or the position of focal point of laser light among Step S120, Step S130 and Step S140.

According to the aforementioned processes, the glass substrate provided with the above-described features can be manufactured. That is, according to the first manufacturing method, a glass substrate provided with a position adjustment function and/or an additional function such as a product management function can be manufactured.

### EXAMPLE

Next, a practical example of the present invention will be described.

### Example 1

A glass substrate having a plurality of holes was manufactured using the following method.

(First Process: Forming Three Holes)

A glass plate to be processed configured of an alkali-free glass with a thickness of 0.2 mm was provided.

One of the surfaces of the glass plate (first surface) was irradiated with a laser light at different positions, to form three holes (first holes).

A CO₂ laser device was used. The irradiation time was 100 μsec. Moreover, the position of focal point was on the first surface. A target aperture diameter of the first holes was set to 72 μm.

(Second Process: Forming One Hole)

Next, using the same laser device (CO₂ laser), one second hole having an aperture diameter different from that of the first holes was formed on the first surface of the glass plate. In this process, the irradiation time of laser light was 430 μsec.

(Third Process: Forming Two Holes)

Next, using the same laser device (CO2 laser), two first holes were formed on the first surface of the glass plate again. The process conditions were the same as that in the first process.

Afterwards, diameters of apertures of the respective holes were measured.

TABLE 1, in the following, shows results of measurement and process conditions for the respective holes as a whole.

TABLE 1

| | | position of focal point | |
|---|---|---|---|
| hole number | irradiation | (mm) (0 mm on first | aperture |
| (processing | time | surface, and negative | diameter |
| order) | (μsec) | inside glass plate) | (μm) |
| 1 | 100 | 0 | 71.8 |
| 2 | 100 | 0 | 72.9 |
| 3 | 100 | 0 | 73.2 |
| 4 | 430 | 0 | 96.0 |
| 5 | 100 | 0 | 72.6 |
| 6 | 100 | 0 | 71.6 |

From the results, it is confirmed that two types of holes having substantially different aperture diameters can be formed by the same laser processing apparatus.

Note that, using a laser microscope (by Keyence Corporation), surface roughness of side walls of the respective holes was measured. From the results, it was found that for any of the holes the arithmetic average roughness Ra of the side walls was 0.02 μm or less.

### Example 2

A glass substrate having a plurality of holes was manufactured using the following method.

(First Process)

A glass plate to be processed configured of an alkali-free glass with a thickness of 0.2 mm was provided.

One of the surfaces of the glass plate (first surface) was irradiated with a laser light at different positions, to form four holes (first holes).

A CO₂ laser device was used. The irradiation time was 100 μsec. Moreover, the position of focal point was on the first surface. A target aperture diameter of the first holes was set to 72 μm.

(Second Process)

Next, using the same laser device (CO2 laser), two second holes having aperture diameters different from that of the first holes were formed on the first surface of the glass plate. In this process, the irradiation time of the laser light was 1000 μsec. Moreover, the position of focal point was a position that was moved inward from the first surface by 0.4 mm.

Afterwards, diameters of apertures of the respective holes were measured.

TABLE 2, in the following, shows results of measurement and process conditions for the respective holes as a whole.

TABLE 2

| | | position of focal point | |
|---|---|---|---|
| hole number | irradiation | (mm) (0 mm on first | aperture |
| (processing | time | surface, and negative | diameter |
| order) | (μsec) | inside glass plate) | (μm) |
| 1 | 100 | 0 | 71.9 |
| 2 | 100 | 0 | 73.2 |
| 3 | 100 | 0 | 71.4 |
| 4 | 100 | 0 | 72.3 |
| 5 | 1000 | −0.4 | 200.1 |
| 6 | 1000 | −0.4 | 200.1 |

From the results, it is confirmed that two types of holes having substantially different aperture diameters can be formed by the same laser processing apparatus.

Note that, using the laser microscope (by Keyence Corporation), surface roughness of side walls of the respective holes was measured. From the results, it was found that for any of the holes the arithmetic average roughness Ra of the side walls was 0.02 μm or less.

As described above, the preferred embodiments and the like have been described in detail. However, the present invention is not limited to the above-described specific embodiments, but various variations and modifications may be made without deviating from the scope of the present invention.

### REFERENCE SIGNS LIST

100 first glass substrate
102 first surface
104 second surface
120 first hole group
122 first hole
124 first aperture
140 second hole group
142 second hole
144 second aperture
160 third hole group
162 third hole
164 third aperture
210 glass plate
212 first surface
214 second surface
220 first hole group
222 first hole
240 second hole group
260 third hole group

What is claimed is:

1. A glass substrate having a plurality of holes, comprising:
a first surface; and
a second surface, the first surface and the second surface being opposite to each other,
wherein each of the holes is arranged so as to have an aperture on the first surface,
wherein the plurality of holes includes a first hole group and a second hole group,
wherein the first hole group includes a plurality of first holes having a first aperture diameter ϕ₁ including a first variation, on the first surface,
wherein the second hole group includes a second hole or a plurality of second holes having a second aperture diameter ϕ₂ including a second variation, on the first surface,
wherein each of the first holes has an aspect ratio of greater than 1, and a surface roughness on an inner wall (arithmetic average roughness Ra) of less than 0.1 μm, and
wherein the second aperture diameter ϕ₂ is greater than the first aperture diameter ϕ₁ by 15% or more, or less than the first aperture diameter ϕ₁ by 15% or more.

2. The glass substrate according to claim 1,
wherein the second holes are holes for position alignment or holes for display marks.

3. The glass substrate according to claim 1,
wherein the second holes are holes for display marks, and
wherein a distinguishable identifier is configured by a combination of the plurality of second holes.

4. The glass substrate according to claim 1,
wherein the plurality of second holes are combined to configure a circular ring.

5. The glass substrate according to claim 1,
wherein the plurality of holes further include a third hole group,
wherein the third hole group includes a plurality of third holes having a third aperture diameter ϕ₃ including a third variation, on the first surface,
wherein the third aperture diameter ϕ₃ is different from the second aperture diameter ϕ₂, and
wherein the third aperture diameter ϕ₃ is greater than the first aperture diameter ϕ₁ by 15% or more, or less than the first aperture diameter ϕ₁ by 15% or more.

6. The glass substrate according to claim 5,
wherein the third variation falls within a range from the third aperture diameter ϕ₃−10% to the third aperture diameter ϕ₃+10%.

7. The glass substrate according to claim 5,
wherein the second holes are holes for position alignment and the third holes are holes for display marks, or the second holes are holes for display marks and the third holes are holes for position alignment.

8. The glass substrate according to claim 5,
wherein the third holes are holes for display marks, and
wherein a distinguishable identifier is configured by a combination of the plurality of third holes.

9. The glass substrate according to claim 5,
wherein the plurality of third holes are combined to configure a circular ring.

10. The glass substrate according to claim 1,
wherein the first holes are through holes.

11. The glass substrate according to claim 1,
wherein the first aperture diameter ϕ₁ of the first holes is selected from a range of 10 μm to 200 μm.

12. The glass substrate according to claim 1
wherein the first variation falls within a range from the first aperture diameter ϕ₁−10% to the first aperture diameter ϕ₁+10%, and/or
the second variation falls within a range from the second aperture diameter ϕ₂−10% to the second aperture diameter ϕ₂+10%.

13. A manufacturing method of a glass substrate having a plurality of holes, the method comprising:
(1) forming a plurality of first holes on a first surface of a glass plate by irradiating the first surface with a first laser light, the glass plate having the first surface and a second surface opposite to each other,
each of the first holes having a first aperture with a first aperture diameter ϕ₁ including a first variation, on the first surface; and
(2) forming a second hole or a plurality of second holes on the first surface of the glass plate by irradiating the first surface with a second laser light,
each of the second holes having a second aperture with a second aperture diameter ϕ₂ including a second variation, on the first surface,
wherein a process of (1) forming the plurality of first holes and a process of (2) forming the second hole or the plurality of second holes are performed in either order, and
wherein the second aperture diameter ϕ₂ is greater than the first aperture diameter ϕ₁ by 15% or more, or less than the first aperture diameter ϕ₁ by 15% or more.

14. The manufacturing method according to claim 13,
wherein the first laser light and the second laser light are emitted from a same laser device.

15. The manufacturing method according to claim 13,
wherein an irradiation time for the second laser light for (2) forming the second hole or the plurality of second holes is different from an irradiation time for the first laser light for (1) forming the plurality of first holes.

16. The manufacturing method according to claim 13,
wherein a position of focal point in a thickness direction of the glass plate of the second laser light for (2) forming the second hole or the plurality of second holes is different from a position of focal point of the first laser light for (1) forming the plurality of first holes.

17. The manufacturing method according to claim 13 further comprising:
(3) forming a third hole or a plurality of third holes on the first surface of the glass plate by irradiating the first surface with a third laser light,
each of the third holes having a third aperture with a third aperture diameter ϕ₃ including a third variation, on the first surface,
wherein a process of (1) forming the plurality of first holes, a process of (2) forming the second hole or the plurality of second holes, and a process of (3) forming the third hole or the plurality of third holes are performed in any order,
wherein the third aperture diameter ϕ₃ is different from the second aperture diameter ϕ₂, and
wherein the third aperture diameter ϕ₃ is greater than the first aperture diameter ϕ₁ by 15% or more, or less than the first aperture diameter ϕ₁ by 15% or more.

18. The manufacturing method according to claim 17,
wherein the third variation falls within a range from the third aperture diameter ϕ₃−10% to the third aperture diameter ϕ₃+10%.

19. The manufacturing method according to claim 17,
wherein the first laser light, the second laser light, and the third laser light are emitted from a same laser device.

20. The manufacturing method according to claim 13,
wherein the first holes are through holes.

21. The manufacturing method according to claim 13,
wherein the first aperture diameter ϕ₁ of the first holes is selected from a range of 10 μm to 200 μm.

22. The manufacturing method according to claim 13
wherein the first variation falls within a range from the first aperture diameter ϕ₁−10% to the first aperture diameter ϕ₁+10%, and/or
the second variation falls within a range from the second aperture diameter ϕ₂−10% to the second aperture diameter ϕ₂+10%.
